(19) United States
(12) Patent Application Publication
(10) Pub. No.: US 2025/0357913 A1
(43) Pub. Date: Nov. 20, 2025

(54) QUARTZ VIBRATING ELEMENT AND QUARTZ VIBRATOR INCLUDING THE SAME

(71) Applicant: Murata Manufacturing Co., Ltd., Nagaokakyo-shi (JP)

(72) Inventor: Taiki GOTO, Nagaokakyo-shi (JP)

(21) Appl. No.: 19/291,753

(22) Filed: Aug. 6, 2025

Related U.S. Application Data
(63) Continuation of application No. PCT/JP2023/040261, filed on Nov. 8, 2023.

(30) Foreign Application Priority Data
Mar. 31, 2023 (JP) 2023-058608

(51) Int. Cl. H03H 9/19; H03H 9/05; H03H 9/10; H03H 9/13

(52) U.S. Cl. CPC H03H 9/19; H03H 9/0595; H03H 9/1035; H03H 9/132

(57) ABSTRACT

A quartz vibrating element that includes: a quartz substrate having: a vibrating portion; a holding portion; and a support arm that connects the vibrating portion and the holding portion; first and second excitation electrodes on first and second surfaces of the vibrating portion, respectively; first and second extended electrodes on the support arm, and electrically connected to the first and second excitation electrodes, respectively, the first extended electrode extending over a first main surface, a first side surface, and a second main surface of the quartz substrate, and the second extended electrode extending over the first main surface, a second side surface, and the second main surface of the quartz substrate.

### CROSS REFERENCE TO RELATED APPLICATIONS

The present application is a continuation of International application No. PCT/JP2023/040261, filed Nov. 8, 2023, which claims priority to Japanese Patent Application No. 2023-058608, filed Mar. 31, 2023, the entire contents of each of which are incorporated herein by reference.

### TECHNICAL FIELD

The present disclosure relates to a quartz vibrating element and a quartz vibrator including the quartz vibrating element.

### BACKGROUND ART

In various electronic devices, such as mobile communication terminals, communication base stations, and home appliances, piezoelectric vibrating elements are used for applications, such as timing devices, sensors, or oscillators. Such a piezoelectric vibrating element includes a piezoelectric piece having a pair of main surfaces and a pair of excitation electrodes provided on the pair of main surfaces of the piezoelectric piece.

For example, Patent Document 1 discloses a piezoelectric device that includes a piezoelectric vibrating piece including a vibrating portion, a frame portion that surrounds the vibrating portion, and a coupling portion that connects the vibrating portion and the coupling portion to each other, a first extended electrode that is extended from an excitation electrode provided on a front surface of the vibrating portion to a front surface of the frame portion through a front surface of the coupling portion, and a second extended electrode extended from an excitation electrode provided on a back surface of the vibrating portion to a back surface of the frame portion through a back surface of the coupling portion.
[Patent Document 1] Japanese Unexamined Patent Application Publication No. 2014-176071

### SUMMARY OF THE DISCLOSURE

However, when the piezoelectric device described in Patent Document 1 has a structure in which the extended electrodes are sufficiently separated from each other to prevent occurrence of unnecessary vibrations caused by inverse piezoelectric effects due to a potential difference between the extended electrodes, the wiring width of the extended electrodes becomes small, electrical resistance increases, and electrical characteristics may degrade.

The present disclosure addresses such circumstances with an object of providing a quartz vibrating element that can suppress the degradation of electrical characteristics and a quartz vibrator including the quartz vibrating element.

According to an aspect of the present disclosure, there is provided a quartz vibrating element including: a quartz substrate that includes: a vibrating portion; a holding portion surrounding the vibrating portion in a plan view of the quartz vibrating element; and a support arm that connects the vibrating portion and the holding portion to each other, wherein, in the support arm, axes obtained by rotating a Y-axis of a crystal and a Z-axis of the crystal about an X-axis of the crystal are defined as a Y′-axis and a Z′-axis, respectively, the quartz substrate has a first main surface and a second main surface that extend in the X-axis and the Z′-axis and face away from each other in the Y′-axis direction, a first side surface that connects end portions of the first main surface and the second main surface on a first side in the Z′-axis direction, and a second side surface that connects end portions of the first main surface and the second main surface on a second side opposite to the first side surface; a first excitation electrode on a first surface of the vibrating portion; a second excitation electrode on a second surface of the vibrating portion; a first extended electrode on the support arm, and electrically connected to the first excitation electrode, the first extended electrode extending over the first main surface, the first side surface, and the second main surface of the quartz substrate; and a second extended electrode on the support arm and electrically connected to the second excitation electrode, the second extended electrode extending over the first main surface, the second side surface, and the second main surface of the quartz substrate.

According to the present disclosure, it is possible to provide a quartz vibrating element that can suppress the degradation of electrical characteristics and a quartz vibrator including the quartz vibrating element.

### BRIEF DESCRIPTION OF THE DRAWINGS

FIG. 1 is an exploded perspective view of a quartz vibrator according to a first embodiment.

FIG. 2 is a cross-sectional view of the quartz vibrator illustrated in FIG. 1, taken along line II-II.

FIG. 3 is a cross-sectional view of the quartz vibrator illustrated in FIG. 1, taken along line III-III.

FIG. 4 is a plan view of a quartz vibrating element according to the first embodiment.

FIG. 5 is a plan view of a lower lid according to the first embodiment.

FIG. 6 is a plan view of a quartz vibrating element according to a second embodiment.

FIG. 7 is a plan view of a lower lid according to the second embodiment.

### DESCRIPTION OF THE PREFERRED EMBODIMENTS

Embodiments of the present disclosure will be described below. In the following description of drawings, the same or similar components are denoted by the same or similar reference numerals. Since the drawings are for illustrative purposes only and the dimensions and the shapes of portions are schematic, the technical scope of the present disclosure should not be interpreted as limited to the embodiments.

In the drawings, an orthogonal coordinate system having the X-axis, the Y′-axis, and the Z′-axis may be provided for convenience to clarify the mutual relationships between the drawings and to facilitate understanding of the positional relationships of components. The X-axes, the Y′-axes, and the Z′-axes in the drawings correspond to each other. The X-axis, the Y′-axis, and the Z′-axis correspond to the crystallographic axes of a quartz substrate 11, which will be described later. The X-axis corresponds to the electric axis (polar axis) of the quartz, the Y-axis corresponds to the mechanical axis of the quartz, and the Z-axis corresponds to the optical axis of the quartz. The Y′-axis and the Z′-axis are obtained by rotating the Y-axis and the Z-axis θ degrees counterclockwise about the X-axis as viewed in the positive direction of the X-axis.

In the following description, the direction parallel to the X-axis is referred to as an X-axis direction, the direction parallel to the Y′-axis is referred to as a Y′-axis direction, and the direction parallel to the Z′-axis is referred to as a Z′-axis direction. In addition, the direction of each of the arrows of the X-axis, the Y′-axis, and the Z′-axis is referred to as positive or +(plus), and the direction opposite to each of the arrows is referred to as negative or −(minus). It should be noted that, for convenience, the +Y′-axis direction is described as an upward direction and the −Y′-axis direction is described as a downward direction, but the upward and downward orientations of a quartz vibrating element 10, a quartz vibrator 1, and a quartz oscillator 100 are not limited. In addition, the plane defined by the X-axis and the Z′-axis is referred to as a Z′X plane, and the same applies to the planes defined by other axes.

### First Embodiment

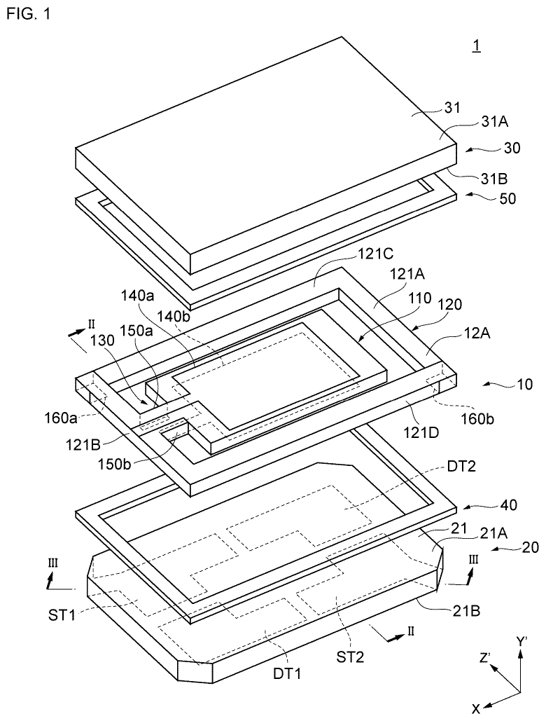

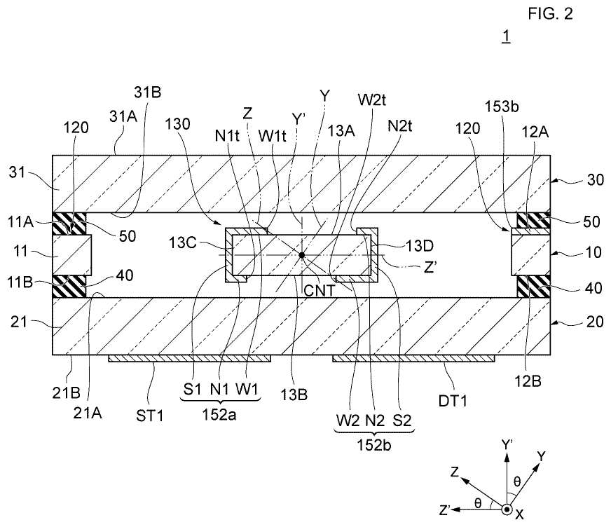

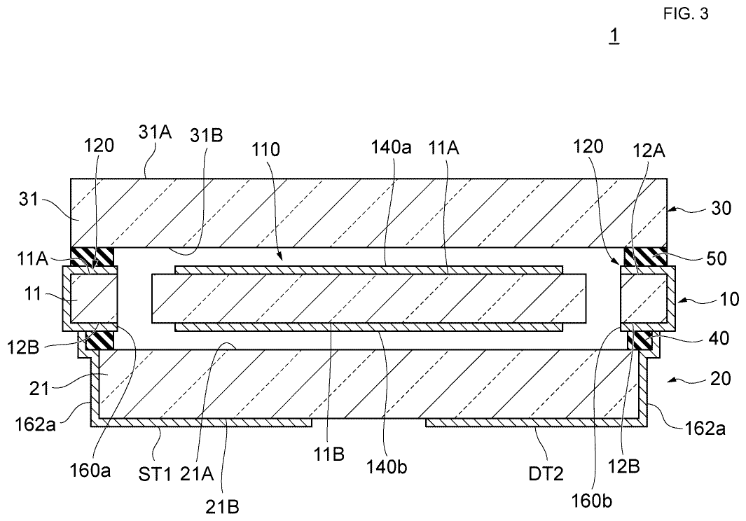

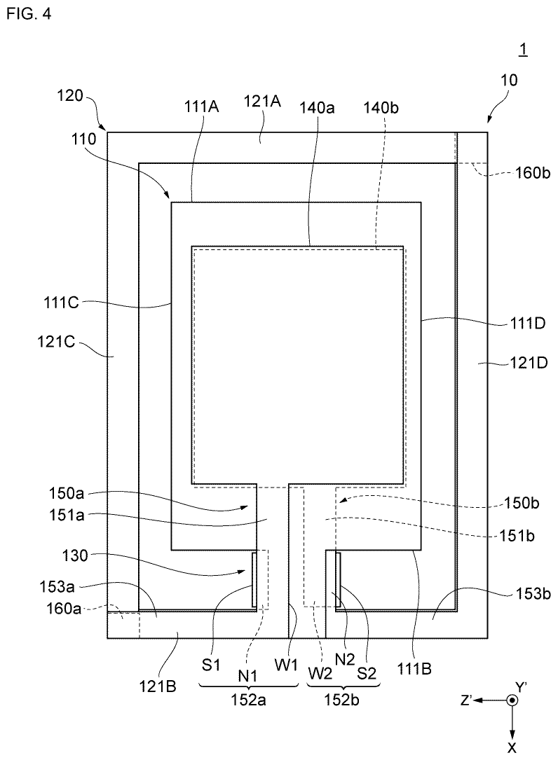

First, the structure of a quartz vibrator according to a first embodiment will be described with reference to FIGS. 1 to 5. FIG. 1 is an exploded perspective view of the quartz vibrator according to the first embodiment. FIG. 2 is a cross-sectional view of the quartz vibrator illustrated in FIG. 1, taken along line II-II. FIG. 3 is a cross-sectional view of the quartz vibrator illustrated in FIG. 1, taken along line III-III. FIG. 4 is a plan view of a lower lid according to the first embodiment.

The quartz vibrator 1 includes a quartz vibrating element 10, a lower lid 20, an upper lid 30, a lower joint portion 40, and an upper joint portion 50. The lower lid 20, the quartz vibrating element 10, and the upper lid 30 are spaced apart in this order in the Y′-axis direction. A Y′-axis direction in which the lower lid 20, the quartz vibrating element 10, and the upper lid 30 are laminated together is defined as a thickness direction. The upper lid 30 corresponds to an example of the first substrate, and the lower lid 20 corresponds to an example of the second substrate. The upper joint portion 50 corresponds to an example of the first joint portion, and the lower joint portion 40 corresponds to an example of the second joint portion.

The quartz vibrating element 10 is an electromechanical energy conversion element that performs conversion between electrical energy and mechanical energy through piezoelectric effects. As illustrated in FIG. 1, the quartz vibrating element 10 includes a vibrating portion 110, a holding portion 120, and a support arm 130.

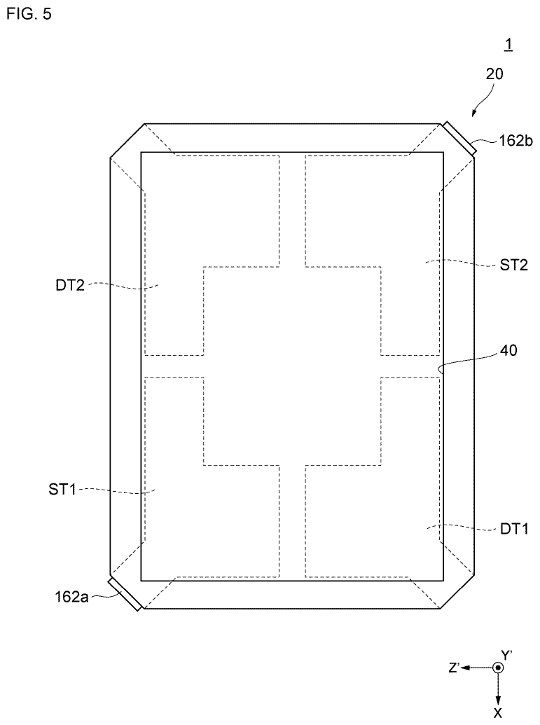

The vibrating portion 110 is excited at a predetermined frequency in accordance with an applied alternating voltage. The vibrating portion 110 is held in a vibration space provided between the lower lid 20 and the upper lid 30 in a vibratable manner. The main vibration of the vibrating portion 110 occurs in a thickness shear vibration mode. As illustrated in FIG. 5, the shape (referred to below as the planar shape) of the vibrating portion 110 as viewed in plan view of XZ′ plane (referred to below simply as plan view) is a rectangle having a pair of short sides 111A and 111B and a pair of long sides 111C and 111D. The pair of short sides 111A and 111B extends in the Z′-axis direction and each other in the axis direction. The pair of long sides 111C and 111D extends in the X-axis direction and face each other in the Z′-axis direction.

It should be noted that the main vibration of the vibrating portion is not limited to the thickness shear vibration mode, and may also be, for example, a thickness longitudinal vibration mode, an extensional vibration mode, a length vibration mode, or a bending vibration mode. In addition, the planar shape of the vibrating portion is not limited to a rectangle and may also be, for example, a square, a polygon, a circle, an ellipse, or a combination of these shapes.

The holding portion 120 is a portion used to hold the vibrating portion 110. The holding portion 120, the lower lid 20, the upper lid 30, the lower joint portion 40, and the upper joint portion 50 constitute a vibration space for the vibrating portion 110. In plan view, the holding portion 120 is formed in a frame shape that surrounds the vibrating portion 110 so as to be spaced apart from the vibrating portion 110. The holding portion 120 includes frame portions 121A, 121B, 121C, and 121D.

The frame portions 121A, 121B, 121C, and 121D are portions of a substantially rectangular frame body that surrounds the vibrating portion 110. As illustrated in FIG. 4, the frame portion 121A is spaced apart from the short side 111A of the vibrating portion 110 in the X-axis direction and extends parallel to the short side 111A in the Z′-axis direction. The frame portion 121B is spaced apart from the short side 111B of the vibrating portion 110 in the X-axis direction and extends parallel to the short side 111B in the Z′-axis direction. The frame portion 121C is spaced apart from the long side 111C of the vibrating portion 110 in the Z′-axis direction and extends parallel to the long side 111C in the X-axis direction. The frame portion 121D is spaced apart from the long side 111D of the vibrating portion 110 in the Z′-axis direction and extends parallel to the long side 111D in the X-axis direction.

Both ends of the frame portion 121C are connected to one end of the frame portion 121A and one end of the frame portion 121B, respectively. Both ends of the frame portion 121D are connected to the other end of the frame portion 121A and the other end of the frame portion 121B, respectively. The frame portion 121A and the frame portion 121B face each other in the X-axis direction with the vibrating portion 110 therebetween. The frame portion 121C and the frame portion 121D face each other in the Z′-axis direction with the vibrating portion 110 therebetween.

It should be noted that the holding portion only needs to be provided at least a portion around the vibrating portion and does not need to have a frame-like shape. The holding portion may be provided in, for example, a rail shape including two parallel frame portions.

The support arm 130 supports the vibrating portion 110 and causes the holding portion 120 to hold the vibrating portion 110. The support arm 130 connects the vibrating portion 110 and the holding portion 120 to each other. As illustrated in FIGS. 1 and 4, the support arm 130 connects the end portions close to the short side 111B of the vibrating portion 110 and the frame portion 121B of the holding portion 120 to each other. The support arm 130 extends along the X-axis.

The lower lid 20 faces the vibrating portion 110, the holding portion 120, and the support arm 130 of the quartz vibrating element 10 with a gap therebetween in the Y′-axis direction. The lower lid 20 is provided in a flat plate shape. As illustrated in FIG. 5, in plan view, the lower lid 20 has a pair of long sides that extend in the X-axis direction and face each other in the Z′-axis direction and a pair of short sides that extend in the Z′-axis direction and face each other in the Z-axis direction. In addition, the pair of long sides and the pair of short sides of the lower lid 20 are connected to each other by sides that are inclined with respect to the pair of long sides and the pair of short sides. That is, cutouts are formed at the four corners of the lower lid 20 in plan view.

The upper lid 30 faces the vibrating portion 110, the holding portion 120, and the support arm 130 of the quartz vibrating element 10 with a gap therebetween in the Y′-axis direction on a side opposite to the lower lid 20. The upper lid 30 is provided in a flat plate shape. As illustrated in FIG. 1, in plan view, the upper lid 30 has a pair of long sides that extend in the X-axis direction and face each other in the Z′-axis direction and a pair of short sides that extend in the Z′-axis direction and face each other in the Z-axis direction. The planar shape of the upper lid 30 is a rectangle.

The lower joint portion 40 and the upper joint portion 50 are provided in a frame shape along the holding portion 120 of the quartz vibrating element 10. The lower joint portion 40 joins the holding portion 120 of the quartz vibrating element 10 and the end portion of the lower lid 20 to each other. The upper joint portion 50 joins the holding portion 120 of the quartz vibrating element 10 and the end portion of the upper lid 30 to each other. The lower joint portion 40 and the upper joint portion 50 are formed of an organic adhesive containing, for example, epoxy, vinyl, acrylic, urethane, or silicone resins.

The materials of the lower joint portion and the upper joint portion are not limited to the organic adhesive and may also be formed of an inorganic adhesive, such as silicon-based adhesives containing water glass or calcium-based adhesives containing cement. The material of the lower joint portion and the upper joint portion may also be low-melting glass (for example, lead borate glass or tin phosphate glass). The material of the lower joint portion and the upper joint portion may also be gold (Au), tin (Sn), copper (Cu), titanium (Ti), aluminum (Al), germanium (Ge), silicon (Si), or a eutectic alloy containing at least one of these metals.

Next, the structures of the quartz vibrating element 10, the lower lid 20, and the upper lid 30 will be described in detail.

The quartz vibrating element 10 includes a quartz substrate 11, a first excitation electrode 140a, a second excitation electrode 140b, a first extended electrode 150a, a second extended electrode 150b, a first connection electrode 160a, and a second connection electrode 160b.

The quartz substrate 11 is continuously provided over the vibrating portion 110, the holding portion 120, and the support arm 130. In the XZ′ plane direction, the quartz substrate 11 extends over substantially the entire regions of the vibrating portion 110, the holding portion 120, and the support arm 130. The quartz substrate 11 is a thin sheet of quartz crystal having the XZ′ plane as the main surface. The quartz substrate 11 is, for example, an AT-cut quartz substrate. That is, the counterclockwise rotation angle θ of the Z′-axis and the Y′-axis from the Z axis and the Y axis as viewed in the positive direction of the X-axis is 35 degrees 15 minutes ±1 minute 30 seconds. The quartz vibrating element 10 using the AT-cut quartz substrate 11 has high frequency stability over a wide temperature range.

As illustrated in FIG. 4, the planar shape of the quartz substrate 11 in the vibrating portion 110 is a rectangle having long sides in the X-axis direction and short sides in the Z′-axis direction. As illustrated in FIG. 3, in the vibrating portion 110, the quartz substrate 11 has an upper surface 11A provided close to the upper lid 30 and a lower surface 11B provided close to the lower lid 20. The upper surface 11A and the lower surface 11B correspond to an example of a pair of main surfaces of the quartz substrate 11 in the vibrating portion 110. The quartz substrate 11 in the vibrating portion 110 has a first short side surface that connects the end portions of the upper surface 11A and the lower surface 11B on the short side 111A close to the frame portion 121A, a second short side surface that connects the end portions of the upper surface 11A and the lower surface 11B on the short side 111B close to the frame portion 121B, a first long side surface that connects the end portions of the upper surface 11A and the lower surface 11B on the long side 111C close to the frame portion 121C, and a second long side surface that connects the end portions of the upper surface 11A and the lower surface 11B on the long side 111D close to the frame portion 121D. The first and second short sides include, for example, a single plane extending along a Y′Z′ plane, but may also include a plurality of inclined surfaces extending in a direction that intersects the Y′Z′ plane or may include a curved surface. In addition, the first and second long side surfaces include, for example, a single plane extending along an XY′ plane, but may also include an inclined surface extending in a direction that intersects the XY′ plane or may include a curved surface.

As illustrated in FIG. 4, the planar shape of the quartz substrate 11 in the holding portion 120 is a rectangular frame having long sides in the X-axis direction and short sides in the Z′-axis direction. In the holding portion 120, the quartz substrate 11 has an upper surface 12A provided close to the upper lid 30 and a lower surface 12B provided close to the lower lid 20 side. The upper surface 12A and the lower surface 12B correspond to an example of a pair of main surfaces of the quartz substrate 11 in the holding portion 120. The quartz substrate 11 in the holding portion 120 has an inner surface that connects the end portions of the upper surface 12A and the lower surface 12B on a side close to the vibrating portion 110, and an outer surface that connects the end portions of the upper surface 12A and the lower surface 12B close to a side opposite to the vibrating portion 110. Each of the inner surfaces and the outer surfaces of the frame portions 121A and 121B includes, for example, a single plane extending along the Y′Z′ plane, but may also include a plurality of inclined surfaces extending in a direction that intersects the Y′Z′ plane or may include a curved surface. Each of the inner surfaces and the outer surfaces of the frame portions 121C and 121D includes, for example, a single plane extending along the XY′ plane, but may also include an inclined surfaces extending in a direction that intersects the XY′ plane or may include a curved surface.

As illustrated in FIG. 4, the planar shape of the quartz substrate 11 in the support arm 130 is a rectangular frame. In the support arm 130, the quartz substrate 11 has an upper surface 13A provided close to the upper lid 30 and a lower surface 13B provided close to the lower lid 20. The upper surface 13A corresponds to an example of the first main surface of the quartz substrate 11 in the support arm 130, and the lower surface 13B corresponds to an example of the second main surface of the quartz substrate 11 in the support arm 130. The quartz substrate 11 in the support arm 130 has a side surface 13C that connects the end portions of the upper surface 13A and the lower surface 13B on a side close to the frame portion 121C, and a side surface 13D that connects the end portions of the upper surface 13A and the lower surface 13B on a side close to the frame portion 121D. The side surface 13C corresponds to an example of the first side surface of the quartz substrate 11 in the support arm 130, and the side surface 13D corresponds to an example of the second side surface of the quartz substrate 11 in the support arm 130. The side surfaces 13C and 13D extend along the XY′ plane. As illustrated in FIG. 2, the shape (referred to below as a cross-sectional shape) of the cross section of the quartz substrate 11 in the support arm 130 parallel to the Y′Z′ plane is a rectangle with the upper surface 13A and the lower surface 13B as long sides and the side surfaces 13C and 13D as the short sides.

It should be noted that the side surface that connects the upper and the lower surfaces of the quartz substrate 11 in the support arm 130 to each other is not limited to a surface including a single plane extending along the XY′ plane, may also include an inclined surface extending in a direction that intersects the XY′ plane, or may include a curved surface.

The thickness of the quartz substrate 11 in the vibrating portion 110, the holding portion 120, and the support arm 130 is uniform. That is, the upper surfaces 11A, 12A, and 13A are flush with each other, and the lower surfaces 11B, 12B, and 13B are flush with each other.

It should be noted that the thickness of the quartz substrate may vary in the vibrating portion, the holding portion, and the support arm, or at the boundaries thereof. For example, in terms of suppressing vibration leakage, the quartz substrate in the vibrating portion may have a mesa-type structure in which the thickness of the center portion including the excitation electrode differs from that of peripheral portions or an inverted mesa-type structure. The quartz substrate in the vibrating portion may have a convex structure in which the thickness changes continuously or may have a bevel structure in which the thickness changes discontinuously. In addition, in terms of suppressing vibration leakage, the thickness of the quartz substrate in the support arm may be larger or smaller than the thickness of the quartz substrate in the vibrating portion.

The first excitation electrode 140a and the second excitation electrode 140b apply a voltage to the quartz substrate 11 of the vibrating portion 110 to excite the vibrating portion 110. As illustrated in FIG. 3, the first excitation electrode 140a is provided on the upper surface 11A of the quartz substrate 11 in the vibrating portion 110, and the second excitation electrode 140b is provided on the lower surface 11B of the quartz substrate 11 in the vibrating portion 110. The first excitation electrode 140a and the second excitation electrode 140b face away from each other with the quartz substrate 11 therebetween. As illustrated in FIG. 4, in plan view, the first excitation electrode 140a and the second excitation electrode 140b are rectangular and are disposed so as to overlap each other substantially entirely.

It should be noted that the planar shapes of the first excitation electrode 140a and the second excitation electrode 140b are not limited to rectangles. The planar shapes of the first excitation electrode 140a and the second excitation electrode 140b may be polygons, circles, ellipses, or a combination of these shapes.

The first extended electrode 150a electrically connects the first excitation electrode 140a and the first connection electrode 160a to each other. As illustrated in FIG. 4, the first extended electrode 150a includes a first portion 151a, a second portion 152a, and a third portion 153a.

The first portion 151a is provided on the upper surface 11A of the quartz substrate 11 in the vibrating portion 110. The first portion 151a is connected to the first excitation electrode 140a. The dimension (referred to below as the width) of the first portion 151a in the Z′-axis direction is substantially equal to, for example, the width of a wide portion W1 of the second portion 152a, which will be described later. However, in terms of reducing the wiring resistance of the first portion 151a, the width of the first portion 151a may be larger than the width of the wide portion W1 of the second portion 152a.

The second portion 152a is continuously provided over the upper surface 13A, the lower surface 13B, and the side surface 13C of the quartz substrate 11 in the support arm 130. The second portion 152a includes the wide portion W1, a side surface portion S1, and a narrow portion N1. The wide portion W1 is provided on the upper surface 13A, the side surface portion S1 is provided on the side surface 13C, and the narrow portion N1 is provided on the lower surface 13B. The wide portion W1 and the side surface portion S1 are connected to each other at the corner portion formed by the upper surface 13A and the side surface 13C. The narrow portion N1 and the side surface portion S1 are connected to each other at the corner portion formed by the lower surface 13B and the side surface 13C. The second portion 152a is connected to the first portion 151a in the wide portion W1. The wide portion W1 corresponds to an example of the first wide portion according to the present disclosure, the narrow portion N1 corresponds to an example of the first narrow portion according to the present disclosure, and the side surface portion S1 corresponds to an example of the first side surface portion according to the present disclosure.

The width of the wide portion W1 is smaller than the width of the narrow portion N1. In plan view, the narrow portion N1 is disposed inside the wide portion W1.

Specifically, the end portion of the wide portion W1 close to the side surface portion S1 overlaps the end portion of the narrow portion N1 close to the side surface portion S1, and an end portion N1t of the narrow portion N1 close to a wide portion W2, which will be described later, is located closer to the side surface portion S1 than is an end portion W1t of the wide portion W1 close to a narrow portion N2, which will be described later.

The third portion 153a is provided on the upper surface 12A of the quartz substrate 11 in the frame portion 121B of the holding portion 120. The third portion 153a extends from the connection portion between the support arm 130 and the frame portion 121B toward the frame portion 121C. One end of the third portion 153a is connected to the wide portion W1 of the second portion 152a at the connection portion between the support arm 130 and the frame portion 121B. The other end of the third portion 153a is electrically connected to the first connection electrode 160a via a side surface electrode provided on the outer surface of the holding portion 120 at a corner portion of the holding portion 120 at which the frame portion 121B and the frame portion 121C are connected to each other.

The second extended electrode 150b electrically connects the second excitation electrode 140b and the second connection electrode 160b to each other. As illustrated in FIG. 4, the second extended electrode 150b includes a first portion 151b, a second portion 152b, and a third portion 153b.

The first portion 151b is provided on the lower surface 11B of the quartz substrate 11 in the vibrating portion 110. The first portion 151b is connected to the second excitation electrode 140b. The width of the first portion 151b is substantially equal to, for example, the width of a wide portion W2 of the second portion 152b, which will be described later. However, in terms of reducing the wiring resistance of the first portion 151b, the width of the first portion 151b may be larger than the width of the wide portion W2 of the second portion 152b.

The second portion 152b is continuously provided over the upper surface 13A, the lower surface 13B, and the side surface 13C of the quartz substrate 11 in the support arm 130. The second portion 152b includes the wide portion W2, a side surface portion S2, and the narrow portion N2. The wide portion W2 is provided on the lower surface 13B, the side surface portion S2 is provided on the side surface 13D, and the narrow portion N2 is provided on the upper surface 13A. The wide portion W2 and the side surface portion S2 are connected to each other at the corner portion formed by the lower surface 13B and the side surface 13C. The narrow portion N2 and the side surface portion S2 are connected to each other at the corner portion formed by the upper surface 13A and the side surface 13C. The second portion 152b is connected to the first portion 151b in the wide portion W2. The wide portion W2 corresponds to an example of the second wide portion according to the present disclosure, the narrow portion N2 corresponds to an example of the second narrow portion according to the present disclosure, and the side surface portion S2 corresponds to an example of the second side surface portion according to the present disclosure.

The width of the wide portion W2 is smaller than the width of the narrow portion N2. In plan view, the narrow portion N2 is located inside the wide portion W2. Specifically, the end portion of the wide portion W2 close to the side surface portion S2 overlaps the end portion of the narrow portion N2 close to the side surface portion S2, and an end portion N2t of the narrow portion N2 close to the wide portion W1 is located closer to the side surface portion S2 than is an end portion W2t of the wide portion W2 close to the narrow portion N1.

The third portion 153b is provided on the upper surface 12A of the quartz substrate 11 in the frame portion 121B of the holding portion 120. The third portion 153b extends from the connection portion between the support arm 130 and the frame portion 121B toward the frame portion 121D, is bent at the corner portion of the holding portion 120 at which the frame portion 121B and frame portion 121D are connected to each other, and extends toward the frame portion 121A. One end of the third portion 153b is connected to the narrow portion N2 of the second portion 152b at the connection portion between the support arm 130 and the frame portion 121B. The other end of the third portion 153b is electrically connected to the second connection electrode 160b via a side surface electrode provided on the outer surface of the holding portion 120 at the corner portion of the holding portion 120 at which the frame portion 121A and the frame portion 121D are connected to each other.

As viewed in cross-sectional view along the Y′Z′ plane of the support arm 130 as illustrated in FIG. 2, the first extended electrode 150a and the second extended electrode 150b are located on sides opposite to each other with respect to the Z-axis that passes through a center CNT of the cross section of the quartz substrate 11, and are located on sides opposite to each other with respect to the Y-axis that passes through the center CNT.

As illustrated in FIG. 2, in the Z-axis direction, the end portion W1t of the wide portion W1 of the first extended electrode 150a close to the narrow portion N2 of the second extended electrode 150b faces the end portion W2t of the wide portion W2 of the second extended electrode 150b close to the narrow portion N1 of the first extended electrode 150a. That is, the end portion W1t and the end portion W2t face each other in a direction rotated (90 degrees+θ) clockwise from the Y′-axis direction orthogonal to the upper surface 13A as viewed in the positive direction of the X-axis, that is, in a direction rotated 0 counterclockwise.

It should be noted that the direction in which the end portion W1t and the end portion W2t face each other is not limited to the Z-axis direction and only needs to be any direction obtained by rotating the Z-axis θ degrees or greater counterclockwise as viewed in the positive direction of the X-axis. That is, the end portion W1t and the end portion W2t may face each other in a direction rotated by an angle smaller than (90 degrees+0) clockwise from the Y′-axis direction, that is, by an angle greater than θ counterclockwise.

The end portion N1t of the narrow portion N1 of the first extended electrode 150a close to the wide portion W2 of the second extended electrode 150b faces the end portion N2t of the narrow portion N2 of the second extended electrode 150b close to the wide portion W1 of the first extended electrode 150a in a direction obtained by rotating the Y-axis by an angle greater than θ degrees clockwise as viewed in the positive direction of the X-axis. When θ is smaller than 45 degrees, the end portion N1t faces the end portion N2t in a direction obtained by rotating the Y-axis by an angle greater than (90 degrees −2×θ) clockwise as viewed in the positive direction of the X-axis. In other words, the end portion N1t faces the end portion N2t in a direction obtained by rotating the Z-axis by an angle smaller than (2×θ) counterclockwise as viewed in the positive direction of the X-axis. When θ is greater than 45 degrees, the end portion N1t faces the end portion N2t in a direction obtained by rotating the Y-axis by an angle smaller than (2×θ) counterclockwise as viewed in the positive direction of the X-axis. In other words, the end portion N1t faces the end portion N2t in a direction obtained by rotating the Z-axis by an angle greater than (180 degrees −2×θ) clockwise as viewed in the positive direction of the X-axis. More preferably, the end portion N1t faces the end portion N2t in a direction obtained by rotating the Y-axis by an angle greater than θ degrees clockwise as viewed in the positive direction of the X-axis.

The direction in which the end portion W1t and the end portion W2t face each other is, for example, the direction in which the center portions in the thickness directions of the end portion W1t and the end portion W2t face each other. However, the direction in which the end portion W1t and the end portion W2t face each other may also be the direction in which the corner portions of the end portion W1t and the end portion W2t close to the quartz substrate 11 face each other. The direction in which the end portion W1t and the end portion W2t face each other may also be the direction in which the corner portions of the end portion W1t and the end portion W2t opposite to the quartz substrate 11 face each other. Similarly, the direction in which the end portion N1t and the end portion N2t face each other may also be the direction in which the center portions in the thickness directions of the end portion N1t and the end portion N2t face each other or may also be the direction in which the corner portions of the end portion N1t and the end portion N2t close to the quartz substrate 11 or the corner portions of the end portion N1t and the end portion N2t opposite to the quartz substrate 11 face each other.

The first excitation electrode 140a is electrically connected to an external terminal through the first connection electrode 160a and the second connection electrode 160b. As illustrated in FIGS. 3 and 4, the first connection electrode 160a is provided on a portion of the lower surface 12B of the quartz substrate 11 that corresponds to the corner portion of the holding portion 120 at which the frame portion 121B and the frame portion 121C are connected to each other. The second connection electrode 160b is provided on a portion of the lower surface 12B of the quartz substrate 11 that corresponds to the corner portion of the holding portion 120 at which the frame portion 121A and the frame portion 121D are connected to each other.

The lower lid 20 includes a quartz substrate 21, power supply terminals ST1 and ST2, and dummy terminals DT1 and DT2. The quartz substrate 21 is a flat substrate that overlaps substantially the entire quartz vibrating element 10 in plan view. The quartz substrate 21 is formed of a quartz crystal with the same cut angle as the quartz substrate 11 of the quartz vibrating element 10. This can reduce the thermal stress caused by the difference in thermal expansion coefficients and the difference in the directions of thermal contraction between the quartz vibrating element 10 and the lower lid 20. As a result, variations in the frequency of the quartz vibrating element 10 can be suppressed. The quartz substrate 21 has an upper surface 21A provided on a side close to the quartz vibrating element 10 and a lower surface 21B provided on a side opposite to the upper surface 21A. The quartz substrate 21 has long sides extending in the X-axis direction and short sides extending in the Z′-axis direction in plan view. In addition, the side surface that connects the upper surface 21A and the lower surface 21B of the quartz substrate 21 overlaps the outer surface of the holding portion 120 in the quartz vibrating element 10 in plan view. A cutout is formed at a corner portion at which a short side and a long side of the quartz substrate 21 are connected to each other. The area of the quartz substrate 21 in plan view is smaller than the area of a quartz substrate 31, which will be described later, in plan view by the area corresponding to the cutouts. The shape of the side surface formed by the cutout at the corner portion of the quartz substrate 21 is, for example, planar. However, the shape of the side surface formed by the cutout at the corner portion of the quartz substrate 21 is not limited to this and may also be a curved surface that is a portion of a cylinder or a prism.

The power supply terminals ST1 and ST2 and the dummy terminals DT1 and DT2 are provided on the lower surface 21B of the quartz substrate 21. The power supply terminals ST1 and ST2 and the dummy terminals DT1 and DT2 correspond to an example of external terminals of the quartz vibrator 1. A drive signal (drive voltage) is applied to the quartz vibrator 1 through the power supply terminals ST1 and ST2. As illustrated in FIGS. 3 and 5, the power supply terminal ST1 is electrically connected to the first connection electrode 160a through a side surface electrode 162a provided on the cutout of the corner portion of the quartz substrate 21 and the outer surface of the lower joint portion 40. The power supply terminal ST2 is electrically connected to the second connection electrode 160b through a side surface electrode 162b provided on the cutout of the corner portion of the quartz substrate 21 and the outer surface of the lower joint portion 40. The dummy terminals DT1 and DT2 are used to balance electrical characteristics, such as electrostatic capacity, and to balance mechanical strength. The dummy terminals DT1 and DT2 are so-called floating electrodes that are not electrically connected to the quartz vibrating element 10.

It should be noted that at least one of the dummy terminals DT1 and DT2 may be a grounding electrode that electrically grounds a portion of the quartz vibrator 1.

The upper lid 30 includes the quartz substrate 31. The quartz substrate 31 is a flat substrate that overlaps substantially the entire quartz vibrating element 10 in plan view. The quartz substrate 31 includes a quartz crystal with the same cut angle as the quartz substrate 11 of the quartz vibrating element 10. This can reduce the thermal stress caused by the difference in thermal expansion coefficients and the difference in the directions of thermal contraction between the quartz vibrating element 10 and the upper lid 30. As a result, variations in the frequency of the quartz vibrating element 10 can be suppressed. The quartz substrate 21 has a lower surface 31B provided on a side close to the quartz vibrating element 10 and an upper surface 31A provided on a side opposite to the lower surface 31B. The quartz substrate 31 has a rectangular shape having a rectangular shape with long sides extending in the X-axis direction and short sides extending in the Z′-axis direction in plan view. In addition, the side surface that connects the upper surface 31A and the lower surface 31B of the quartz substrate 31 overlaps the outer surface of the holding portion 120 in the quartz vibrating element 10 in plan view.

It should be noted that the cut angles of the quartz substrates included in the lower lid and the upper lid are not particularly limited and may differ from the cut angle of the quartz substrate included in the quartz vibrating element. In addition, the lower lid and upper lid may include a glass substrate, a silicon substrate, a ceramic substrate, or a metal substrate instead of a quartz substrate.

As described above, in the quartz vibrating element 10 according to the embodiment, the first extended electrode 150a is provided on the upper surface 13A, the lower surface 13B, and the side surface 13C of the quartz substrate 11 in the support arm 130, and the second extended electrode 150b is provided on the upper surface 13A, the lower surface 13B, and the side surface 13D of the quartz substrate 11 in the support arm 130.

As a result, the cross-sectional areas of the first extended electrode 150a and the second extended electrode 150b in the support arm 130 can be increased as compared with the structure in which one of the extended electrodes is provided on at least a portion of the upper surface and the side surface of the quartz substrate in the support arm and the other extended electrode is provided on at least a portion of the lower surface and the side surface. Accordingly, decreases in the wiring resistances of the first extended electrode 150a and the second extended electrode 150b can suppress degradation of the electrical characteristics of the quartz vibrating element 10, that is, an increase in the crystal impedance (CI) value.

In the aspect described above, the first extended electrode 150a includes the wide portion W1 provided on the upper surface 13A, the narrow portion N1 provided on the lower surface 13B, and the side surface portion S1 provided on the side surface 13C, and the second extended electrode 150b includes the wide portion W2 provided on the lower surface 13B, the narrow portion N2 provided on the upper surface 13A, and the side surface portion S2 provided on the side surface 13D.

As a result, the cross-sectional areas of the first extended electrode 150a and the second extended electrode 150b can be increased while the distance between the first extended electrode 150a and the second extended electrode 150b is maintained. That is, by suppression of the generation of parasitic capacitance and unnecessary vibrations between the first extended electrode 150a and the second extended electrode 150b, a decrease in the Q value due to energy loss can be suppressed and an increase in the CI value can be suppressed. In addition, by reduction of the wiring resistances of the first extended electrode 150a and the second extended electrode 150b, an increase in the CI value can be suppressed.

In the aspect described above, the end portion W1t of the wide portion W1 faces the end portion W2t of the wide portion W2 in a direction obtained by rotating the Z-axis θ degrees or greater counterclockwise as viewed in the positive direction of the X-axis.

As a result, in the Z-axis direction in which no piezoelectric effects occur, even when the first extended electrode 150a and the second extended electrode 150b face away from each other, unnecessary vibrations do not occur. In addition, when the first extended electrode 150a and the second extended electrode 150b face away from each other in a direction obtained by rotating the Z-axis θ degrees or greater counterclockwise as viewed in the positive direction of the X-axis, the distance between the first extended electrode 150a and the second extended electrode 150b becomes larger than in a structure in which the first extended electrode and the second extended electrode face each other in a direction obtained by rotating the Z-axis in the reverse direction. As a result, the electric field strength acting on the quartz substrate 11 between the first extended electrode 150a and the second extended electrode 150b is reduced, and accordingly, the occurrence of unnecessary vibrations can be suppressed. Therefore, a decrease in the Q value due to energy loss can be suppressed and an increase in the CI value can be suppressed.

In the aspect described above, the end portion N1t of the narrow portion N1 faces the end portion N2t of the narrow portion N2 in a direction obtained by rotating the Y-axis by an angle greater than θ degrees clockwise as viewed in the positive direction of the X-axis.

As a result, as viewed in the positive direction of the X-axis, the distance between the narrow portion N1 and the narrow portion N2 becomes larger than in a structure in which these narrow portions face each other in a direction obtained by rotating the Y-axis by an angle of θ degrees or smaller clockwise as viewed in the positive direction of the X-axis. As a result, the electric field strength acting on the quartz substrate 11 between the narrow portions N1 and N2 is reduced, and accordingly, the occurrence of unnecessary vibrations can be suppressed. Accordingly, a decrease in the Q value due to energy loss can be suppressed and an increase in the CI value can be suppressed.

In the aspect described above, the first extended electrode 150a and the second extended electrode 150b are located opposite to each other with respect to the Z-axis that passes through the center CNT of a Y′Z′ cross section of the quartz substrate 11 in the support arm 130 and are located opposite to each other with respect to the Y-axis that passes through the center CNT.

As a result, the distance between the first extended electrode 150a and the second extended electrode 150b becomes larger. As a result, the electric field strength acting on the quartz substrate 11 between the first extended electrode 150a and the second extended electrode 150b is reduced, and accordingly, the occurrence of unnecessary vibrations can be suppressed. Therefore, a decrease in the Q value due to energy loss can be suppressed and an increase in the CI value can be suppressed.

In the aspect described above, the vibrating portion 110 has long sides extending in the X-axis direction and short sides extending in the Z′-axis direction in plan view, and the support arm 130 extends in the X-axis direction from the short side of the vibrating portion 110.

As a result, it is possible to increase the order of the bending vibrations to be superimposed on thickness shear vibrations that are primary vibrations. When the order of bending vibrations is increased, the vibration leakage of bending vibrations is reduced. Accordingly, a decrease in the Q value due to energy loss can be suppressed and an increase in the CI value can be suppressed.

In the aspect described above, the shape of the XZ′ cross section of the quartz substrate 11 in the support arm 130 is a rectangle.

As a result, since the symmetry of the cross-sectional shape of the quartz substrate 11 in the support arm 130 is high, the stress when acceleration or impact acts on the quartz vibrator 1 is evenly distributed. Accordingly, the shock resistance of the quartz vibrating element 10 is improved.

Other embodiments will be described below. It should be noted that components that are the same as or similar to those illustrated in the first embodiment are denoted by similar reference numerals, and the descriptions thereof are omitted as appropriate. In addition, the same effect resulting from the same component will not be described one by one.

### Second Embodiment

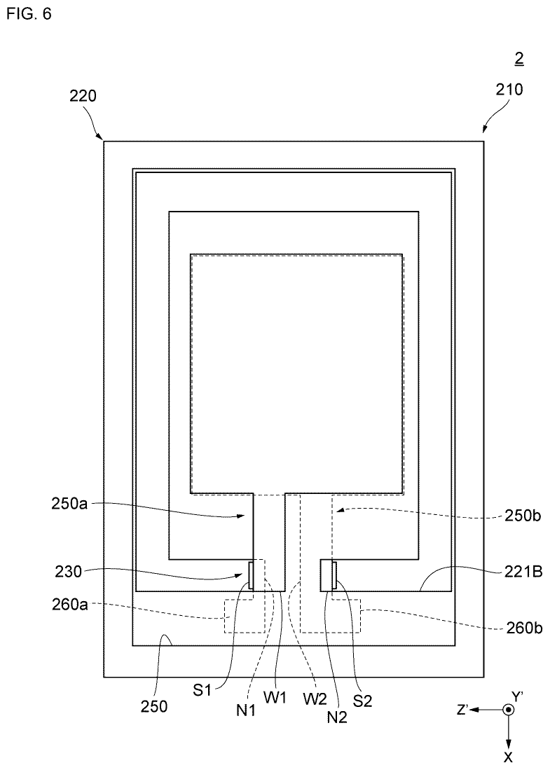

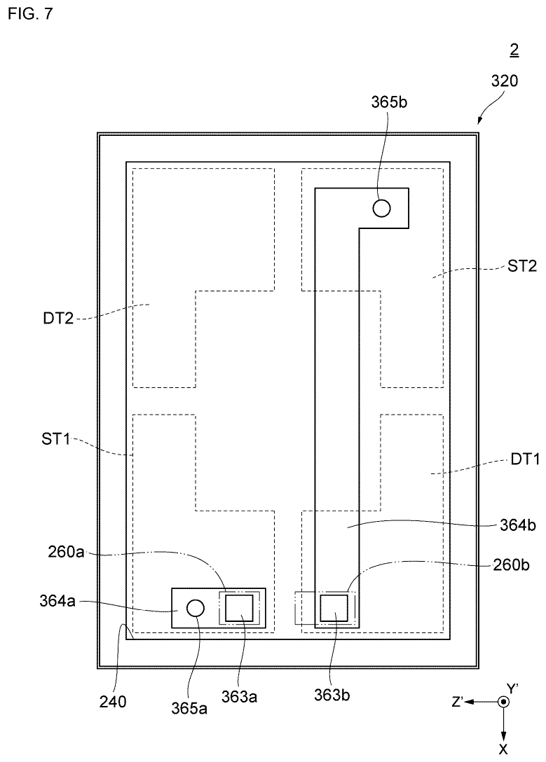

Next, the structure of a quartz vibrator 2 according to a second embodiment will be described with reference to FIGS. 6 and 7. FIG. 6 is a plan view of the quartz vibrating element according to the second embodiment. FIG. 7 is a plan view of a lower lid according to the second embodiment.

In the quartz vibrator 2, the materials of a lower joint portion 240 and an upper joint portion 250 are metal. That is, the quartz vibrating element 210 is metal-joined to the lower lid 320, and the quartz vibrating element 210 is metal-joined to the upper lid 30. A first connection electrode 260a and a second connection electrode 260b are provided at the center portion in the Z′-axis direction of a frame portion 221B of the holding portion 220. In plan view, the first connection electrode 260a and the second connection electrode 260b are provided in a region surrounded by the lower joint portion 240 and are spaced apart from the lower joint portion 240. The narrow portion N1 of a first extended electrode 250a is connected to the first connection electrode 260a, and the wide portion W2 of a second extended electrode 250b is connected to the second connection electrode 260b.

Upper surface electrodes 364a and 364b are provided on the upper surface 21A of the lower lid 320. A conductive portion 363a is provided between the upper surface electrode 364a and the first connection electrode 260a, and a conductive portion 363a is also provided between the upper surface electrode 364b and the second connection electrode 260b. A through-electrode 365a that passes through the quartz substrate 21 in the Y′-axis direction is provided between the upper surface electrode 364a and the power supply terminal ST1, and a through-electrode 365b that passes through the quartz substrate 21 in the Y′-axis direction is provided between the upper surface electrode 364b and the power supply terminal ST2.

The upper surface electrode 364a is electrically connected to the first connection electrode 260a via the conductive portion 363a. In plan view, the upper surface electrode 364a extends from a region that overlaps the conductive portion 363a to a region that overlaps the through-electrode 365a. The upper surface electrode 364a is electrically connected to the power supply terminal ST1 via the through-electrode 365a. The upper surface electrode 364b is electrically connected to the second connection electrode 260b via a conductive portion 363b. In plan view, the upper surface electrode 364b extends from a region that overlaps the conductive portion 363b to a region that overlaps the through-electrode 365b. The upper surface electrode 364b is electrically connected to the power supply terminal ST2 via the through-electrode 365b.

The embodiments of the present disclosure are applicable as appropriate to devices that perform electromechanical energy conversion through piezoelectric effects, such as timing devices, sound generators, oscillators, and load sensors, without being particularly limited.

As described above, according to one aspect of the present disclosure, it is possible to provide a quartz vibrating element that can suppress the degradation of electrical characteristics and a quartz vibrator including the quartz vibrating element.

It should be noted that the embodiments described above are provided to facilitate the understanding of the present disclosure and are not intended to limit the interpretation of the present disclosure. The present disclosure may be modified or improved without departing from the spirit, and equivalents thereof are also included in the present disclosure. That is, any design modifications made by those skilled in the art as appropriate to the embodiment and/or the modifications are also included within the scope of the present disclosure as long as they have the features of the present disclosure. For example, the components included in the embodiment and/or the modification and the arrangement, the materials, the conditions, the shapes, the sizes, and the like of the components are not limited to those illustrated and can be changed as appropriate. In addition, the embodiments and the modifications are illustrative, and it will be appreciated that partial substitutions or combinations of the structures illustrated in different embodiments and/or modifications are possible, and these are also included within the scope of the present disclosure as long as they have the features of the present disclosure.

### REFERENCE SIGNS LIST

1 quartz vibrator
10 quartz vibrating element
11 quartz substrate
11A, 12A, 13A upper surface
11B, 12B, 13B lower surface
13C, 13D side surface
110 vibrating portion
120 holding portion
121A, 121B, 121C, 121D frame portion
130 support arm
140a first excitation electrode
140b second excitation electrode
150a first extended electrode
150b second extended electrode
151a, 151b first portion
152a, 152b second portion
153a, 153b third portion
W1, W2 wide portion
N1, N2 narrow portion
S1, S2 side surface portion
160a first connection electrode
160b second connection electrode
20 lower lid
30 upper lid
40 lower joint portion
50 upper joint portion

1. A quartz vibrating element including:
a quartz substrate that includes:
a vibrating portion;
a holding portion surrounding the vibrating portion in a plan view of the quartz vibrating element; and
a support arm that connects the vibrating portion and the holding portion to each other,
wherein, in the support arm, axes obtained by rotating a Y-axis of a crystal and a Z-axis of the crystal about an X-axis of the crystal are defined as a Y′-axis and a Z′-axis, respectively,
the quartz substrate has a first main surface and a second main surface that extend in the X-axis and the Z′-axis and face away from each other in the Y′-axis direction,
a first side surface that connects end portions of the first main surface and the second main surface on a first side in the Z′-axis direction, and
a second side surface that connects end portions of the first main surface and the second main surface on a second side opposite to the first side surface;
a first excitation electrode on a first surface of the vibrating portion;
a second excitation electrode on a second surface of the vibrating portion;
a first extended electrode on the support arm, and electrically connected to the first excitation electrode, the first extended electrode extending over the first main surface, the first side surface, and the second main surface of the quartz substrate; and
a second extended electrode on the support arm and electrically connected to the second excitation electrode, the second extended electrode extending over the first main surface, the second side surface, and the second main surface of the quartz substrate.

2. The quartz vibrating element according to claim 1,
wherein a dimension of the quartz substrate in the Z′-axis direction in the support arm is larger than a dimension of the quartz substrate in the Y′-axis direction in the support arm,
the first extended electrode includes a first wide portion on the first main surface, a first side surface portion on the first side surface, and a first narrow portion on the second main surface and that has a dimension smaller than a dimension of the first wide portion in the Z′-axis direction, and
the second extended electrode includes a second wide portion on the second main surface, a second side surface portion on the second side surface, and a second narrow portion on the first main surface and that has a dimension smaller than a dimension of the second wide portion in the Z′-axis direction.

3. The quartz vibrating element according to claim 2, wherein a first end portion of the first wide portion proximal to the second narrow portion faces a second end portion of the second wide portion proximal to the first narrow portion in a direction obtained by rotating the Z-axis θ degrees or greater counterclockwise as viewed in a positive direction of the X-axis.

4. The quartz vibrating element according to claim 3, wherein a third end portion of the first narrow portion proximal to the second wide portion faces a fourth end portion of the second narrow portion proximal to the first wide portion in a direction obtained by rotating the Y-axis by an angle greater than θ degrees clockwise as viewed in the positive direction of the X-axis.

5. The quartz vibrating element according to claim 2, wherein a third end portion of the first narrow portion proximal to the second wide portion faces a fourth end portion of the second narrow portion proximal to the first wide portion in a direction obtained by rotating the Y-axis by an angle greater than θ degrees clockwise as viewed in a positive direction of the X-axis.

6. The quartz vibrating element according to claim 1, wherein, in a cross section of the quartz substrate defined by the X-axis and the Z′-axis in the support arm, the first extended electrode and the second extended electrode are located on sides opposite to each other with respect to the Z-axis that passes through a center of the cross section of the quartz substrate in the support arm and are located on sides opposite to each other with respect to the Y-axis that passes through a center of the cross section of the quartz substrate in the support arm.

7. The quartz vibrating element according to claim 1,
wherein, in the plan view, the vibrating portion has a first side that extends in the X-axis direction and a second side that extends in the Z′-axis direction, the first side being longer than the second side, and
the support arm extends in the X-axis direction from the second side of the vibrating portion.

8. The quartz vibrating element according to claim 1, wherein a shape of a cross section of the quartz substrate in the support arm defined by the X-axis and the Z′-axis is a rectangle.

9. The quartz vibrating element according to claim 1, wherein the quartz substrate is AT-cut.

10. A quartz vibrator comprising:
the quartz vibrating element according to claim 1;
a first substrate spaced apart from the quartz vibrating element in the Y′-axis direction;
a second substrate spaced apart from the quartz vibrating element in the Y′-axis direction;
a first joint portion that joins the holding portion of the quartz vibrating element and the first substrate to each other; and
a second joint portion that joins the holding portion of the quartz vibrating element and the second substrate to each other.

11. The quartz vibrator according to claim 10,
wherein a dimension of the quartz substrate in the Z′-axis direction in the support arm is larger than a dimension of the quartz substrate in the Y′-axis direction in the support arm,
the first extended electrode includes a first wide portion on the first main surface, a first side surface portion on the first side surface, and a first narrow portion on the second main surface and that has a dimension smaller than a dimension of the first wide portion in the Z′-axis direction, and
the second extended electrode includes a second wide portion on the second main surface, a second side surface portion on the second side surface, and a second narrow portion on the first main surface and that has a dimension smaller than a dimension of the second wide portion in the Z′-axis direction.

12. The quartz vibrator according to claim 11, wherein a first end portion of the first wide portion proximal to the second narrow portion faces a second end portion of the second wide portion proximal to the first narrow portion in a direction obtained by rotating the Z-axis θ degrees or greater counterclockwise as viewed in a positive direction of the X-axis.

13. The quartz vibrator according to claim 12, wherein a third end portion of the first narrow portion proximal to the second wide portion faces a fourth end portion of the second narrow portion proximal to the first wide portion in a direction obtained by rotating the Y-axis by an angle greater than θ degrees clockwise as viewed in the positive direction of the X-axis.

14. The quartz vibrator according to claim 11, wherein a third end portion of the first narrow portion proximal to the second wide portion faces a fourth end portion of the second narrow portion proximal to the first wide portion in a direction obtained by rotating the Y-axis by an angle greater than θ degrees clockwise as viewed in a positive direction of the X-axis.

15. The quartz vibrator according to claim 10, wherein, in a cross section of the quartz substrate defined by the X-axis and the Z′-axis in the support arm, the first extended electrode and the second extended electrode are located on sides opposite to each other with respect to the Z-axis that passes through a center of the cross section of the quartz substrate in the support arm and are located on sides opposite to each other with respect to the Y-axis that passes through a center of the cross section of the quartz substrate in the support arm.

16. The quartz vibrator according to claim 10,
wherein, in the plan view, the vibrating portion has a first side that extends in the X-axis direction and a second side that extends in the Z′-axis direction, the first side being longer than the second side, and
the support arm extends in the X-axis direction from the second side of the vibrating portion.

17. The quartz vibrator according to claim 10, wherein a shape of a cross section of the quartz substrate in the support arm defined by the X-axis and the Z′-axis is a rectangle.

18. The quartz vibrator according to claim 10, wherein the quartz substrate is AT-cut.
